(19) United States
(12) Patent Application Publication
(10) Pub. No.: US 2025/0301727 A1
(43) Pub. Date: Sep. 25, 2025

(54) BACKSIDE CONTACT

(71) Applicant: INTERNATIONAL BUSINESS MACHINES CORPORATION, ARMONK, NY (US)

(72) Inventors: HUIMEI ZHOU, Albany, NY (US); Ruilong Xie, Niskayuna, NY (US); Chen Zhang, Santa Clara, CA (US); Kisik Choi, Watervliet, NY (US)

(21) Appl. No.: 18/611,770

(22) Filed: Mar. 21, 2024

(51) Int. Cl. H01L 29/06; H01L 27/088; H01L 29/08; H01L 29/423; H01L 29/66; H01L 29/775; H01L 29/786

(52) U.S. Cl. CPC H10D 62/118; H10D 30/014; H10D 30/43; H10D 30/6735; H10D 30/6757; H10D 62/115; H10D 62/151; H10D 64/017; H10D 84/83

(57) ABSTRACT

A semiconductor structure including a source drain region directly adjacent to a nanosheet stack, a bottom contact directly below the source drain region, the bottom contact includes a top portion directly below the source drain region, a middle portion directly below the top portion, a first bottom portion directly below the middle portion, a second bottom portion directly below the first bottom portion, where the middle portion is more narrow than the top portion and more narrow than the first bottom portion. A semiconductor structure including a bottom contact directly below a source drain region, the bottom contact includes a top portion directly below the source drain region, a middle portion directly below the top portion, a first bottom portion directly below the middle portion, where the middle portion is more narrow than the top portion and more narrow than the first bottom portion.

### BACKGROUND

The present invention generally relates to semiconductor structures, and more particularly to a backside contact and method of forming the same.

Complementary metal-oxide-semiconductor (CMOS) technology is commonly used for field effect transistors (hereinafter “FET”) as part of advanced integrated circuits (hereinafter “IC”), such as central processing units (hereinafter “CPUs”), memory, storage devices, and the like. As demands to reduce the dimensions of transistor devices continue, nanosheet FETs help achieve a reduced FET device footprint while maintaining FET device performance. A nanosheet device contains one or more layers of semiconductor channel material portions having a vertical thickness that is substantially less than its width. A nanosheet FET includes a plurality of stacked nanosheets extending between a pair of source/drain epitaxial regions. The device may be a gate all around device or transistor in which a gate surrounds a portion of the nanosheet channel. Backside contact integrity is important for good connections and avoidance of shorts.

### SUMMARY

According to an embodiment of the present invention, a semiconductor structure is provided. The semiconductor structure including a source drain region directly adjacent to a nanosheet stack, and a bottom contact directly below the source drain region, where the bottom contact includes top portion directly below the source drain region, a middle portion directly below the top portion, a first bottom portion directly below the middle portion and a second bottom portion directly below the first bottom portion, where the middle portion is more narrow than the top portion and more narrow than the first bottom portion.

According to an embodiment of the present invention, a semiconductor structure is provided. The semiconductor structure including a bottom contact directly below a source drain region, where the bottom contact includes a top portion directly below the source drain region, a middle portion directly below the top portion and a first bottom portion directly below the middle portion, where the middle portion is more narrow than the top portion and more narrow than the first bottom portion

According to an embodiment of the present invention, a semiconductor structure is provided. The semiconductor structure including a source drain region directly adjacent to a nanosheet stack, and a bottom contact directly below the source drain region, where the bottom contact includes top portion directly below the source drain region and a middle portion directly below the top portion, where the middle portion is more narrow than the top portion and more narrow than the first bottom portion.

### BRIEF DESCRIPTION OF THE DRAWINGS

The following detailed description, given by way of example and not intended to limit the invention solely thereto, will best be appreciated in conjunction with the accompanying drawings, in which:

FIG. 1 illustrates a top view of a semiconductor structure at an intermediate stage of fabrication, according to an exemplary embodiment;

FIGS. 2 and 3 each illustrate a cross-sectional view of the semiconductor structure of FIG. 1 along section line X-X and Y-Y, respectively, according to an embodiment of the invention;

FIGS. 4 and 5 each illustrate a cross-sectional view of the structure along section line X-X and Y-Y, respectively and illustrates removal of a substrate, according to an embodiment of the invention;

FIGS. 6 and 7 each illustrate a cross-sectional view of the structure along section line X-X and Y-Y, respectively and illustrates formation of a first insulator, second insulator and third insulator, according to an embodiment of the invention;

FIGS. 8 and 9 each illustrate a cross-sectional view of the structure along section line X-X and Y-Y, respectively and illustrates formation of a mask and removal of a portion of the third insulator, according to an embodiment of the invention;

FIGS. 10 and 11 each illustrate a cross-sectional view of the structure along section line X-X and Y-Y, respectively and illustrates formation of a liner, according to an embodiment of the invention;

FIGS. 12 and 13 each illustrate a cross-sectional view of the structure along section line X-X and Y-Y, respectively and illustrates removal of a portion of the liner, according to an embodiment of the invention;

FIGS. 14 and 15 each illustrate a cross-sectional view of the structure along section line X-X and Y-Y, respectively and illustrates removal of a portion of the second insulator, removal of remaining portions of the liner and removal of a portion of a sacrificial placeholder, according to an embodiment of the invention;

FIGS. 16 and 17 each illustrate a cross-sectional view of the structure along section line X-X and Y-Y, respectively and illustrates removal of remaining portions of the sacrificial placeholder, according to an embodiment of the invention; and

FIGS. 18 and 19 each illustrate a cross-sectional view of the structure along section line X-X and Y-Y, respectively and illustrates formation of a contact, according to an embodiment of the invention.

The drawings are not necessarily to scale. The drawings are merely schematic representations, not intended to portray specific parameters of the invention. For clarity and ease of illustration, scale of elements may be exaggerated. The drawings are intended to depict only typical embodiments of the invention. In the drawings, like numbering represents like elements.

### DETAILED DESCRIPTION

Detailed embodiments of the claimed structures and methods are disclosed herein; however, it can be understood that the disclosed embodiments are merely illustrative of the claimed structures and methods that may be embodied in various forms. This invention may, however, be embodied in many different forms and should not be construed as limited to the exemplary embodiments set forth herein. In the description, details of well-known features and techniques may be omitted to avoid unnecessarily obscuring the presented embodiments.

References in the specification to “one embodiment”, “an embodiment”, “an example embodiment”, etc., indicate that the embodiment described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described.

For purposes of the description hereinafter, the terms “upper”, “lower”, “right”, “left”, “vertical”, “horizontal”, “top”, “bottom”, and derivatives thereof shall relate to the disclosed structures and methods, as oriented in the drawing figures. It will be understood that when an element as a layer, region or substrate is referred to as being “on” or “over” another element, it can be directly on the other element or intervening elements may also be present. In contrast, when an element is referred to as being “directly on” or “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Also, the term “sub-lithographic” may refer to a dimension or size less than current dimensions achievable by photolithographic processes, and the term “lithographic” may refer to a dimension or size equal to or greater than current dimensions achievable by photolithographic processes. The sub-lithographic and lithographic dimensions may be determined by a person of ordinary skill in the art at the time the application is filed.

The terms substantially, substantially similar, about, or any other term denoting functionally equivalent similarities refer to instances in which the difference in length, height, or orientation convey no practical difference between the definite recitation (e.g. the phrase sans the substantially similar term), and the substantially similar variations. In one embodiment, substantial (and its derivatives) denote a difference by a generally accepted engineering or manufacturing tolerance for similar devices, up to, for example, 10% deviation in value or 10° deviation in angle.

In the interest of not obscuring the presentation of embodiments of the present invention, in the following detailed description, some processing steps or operations that are known in the art may have been combined together for presentation and for illustration purposes and in some instances may have not been described in detail. In other instances, some processing steps or operations that are known in the art may not be described at all. It should be understood that the following description is rather focused on the distinctive features or elements of various embodiments of the present invention.

A nanosheet field effect transistor (hereinafter “FET”) may be formed from alternating layers of silicon and silicon germanium, which are then formed into stacked nanosheets. A gate all around structure may be formed on all vertical sides and on a horizontal top surface of a section of the nanosheets. Source-drain structures may be formed at the opposite ends of the stacked nanosheet structures.

Proper alignment for direct backside contact patterning is challenging, and can be a problem when a BSCA (backside contact) critical dimension (CD) is too large or too small. When a BSCA has a CD which is too large, there is a chance of shorting between the BSCA to gate (PC) short, or a chance of shorting between a BSCA and a neighboring source drain place holder which does not have a backside contact. For a BSCA CD which is too small, there is a chance that an overlap area of the BSCA to a source drain epitaxy is too small to provide good contact resistivity.

In an embodiment of this invention, a contact to a source drain epitaxy through the backside or through a lower portion of a semiconductor structure is formed with improved reliability. This is achieved by building up several layers of different dielectric material, each of which can be selectively removed. Selective removal of each layer allows for an opening with an enlarged CD at a greater distance from a sacrificial placeholder for a bottom contact to a source drain. An additional spacer is used when removing the last or topmost dielectric layer, helping to keep enough space for backside CA and improve reliability.

A sacrificial placeholder is formed in a substrate and a source drain is formed over the sacrificial placeholder and between channels of a nanosheet FET. After forming contacts and back end of line (“BEOL”) layers, a carrier wafer is mounted on a upper portion of the semiconductor structure. The semiconductor structure is turned upside down for further processing though a bottom of the semiconductor structure or a bottom of the substrate at a lower portion of the semiconductor structure. The substrate is removed.

In an embodiment of this invention a first insulator, a second insulator and a third insulator are formed on the bottom of the semiconductor structure. The first, second and third insulator are formed of different materials allowing selective removal. The first insulator is formed below a bottom dielectric isolation. The bottom dielectric isolation is below the semiconductor layers of the nanosheet FET and below the source drain of the nanosheet FET. The first insulator surrounds a portion of the sacrificial placeholder extending below the source drain. The second insulator covers a remaining portion of the sacrificial placeholder and covers the first insulator below the first insulator. The third insulator covers the second insulator below the second insulator. An opening in the third insulator is formed aligned below the sacrificial placeholder. A liner is blanked conformally formed on a lower surface of the semiconductor structure. Horizontal portions of the liner are selectively removed. The liner protects vertical side surfaces of the third insulator when a portion of the second insulator is removed which is vertically aligned with the opening in the third insulator, helping to prevent unintended removal additional portions of the third insulator. A portion of the sacrificial placeholder is exposed and then removed.

A portion of the first insulator is removed, vertically aligned with the removed portions of the second and third insulator. Remaining portions of the sacrificial placeholder are removed, exposing a lower horizontal surface of the source drain. A contact is formed to the source drain.

When forming contacts to the source drain from a lower portion of the semiconductor structure, openings must be formed through material below the source drain. By forming the first insulator, the second insulator and the third insulator on the bottom of the semiconductor structure, along with a liner protecting vertical side surfaces of the third insulator, portions of each of the first, second, third insulator may be selectively removed. The selective removal of each of the first, second, third insulator reduces a chance of the openings to the source drain overlapping and causing shorts between adjacent source drains when contacts are formed in the openings.

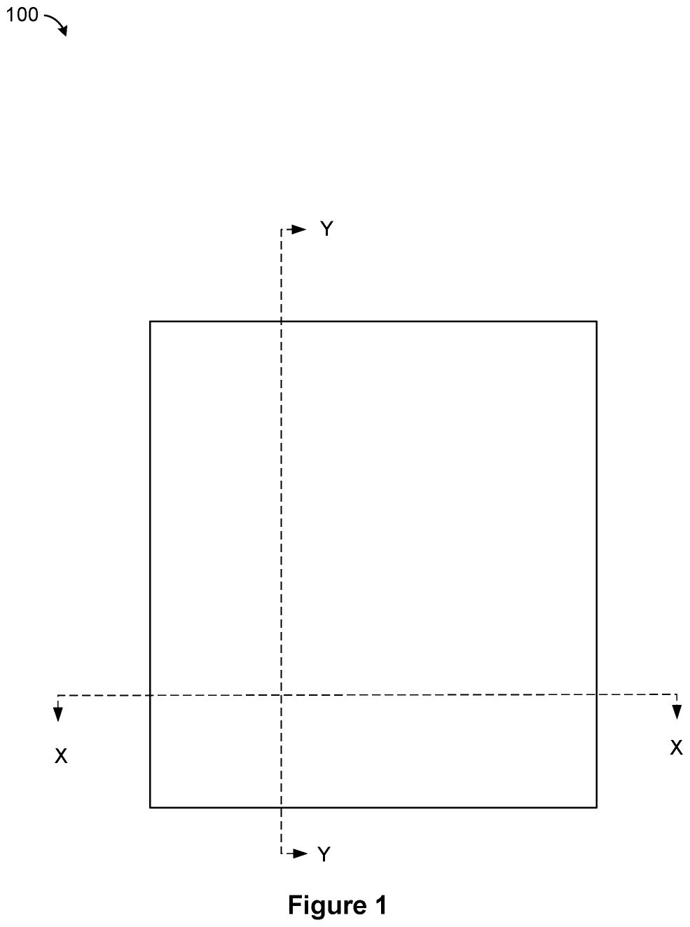

The present invention generally relates to semiconductor structures, and more particularly to backside contact. Exemplary embodiments of a backside contact are described in detail below by referring to the accompanying drawings in FIGS. 1 to 19. Those skilled in the art will readily appreciate that the detailed description given herein with respect to these figures is for explanatory purposes as the invention extends beyond these limited embodiments.

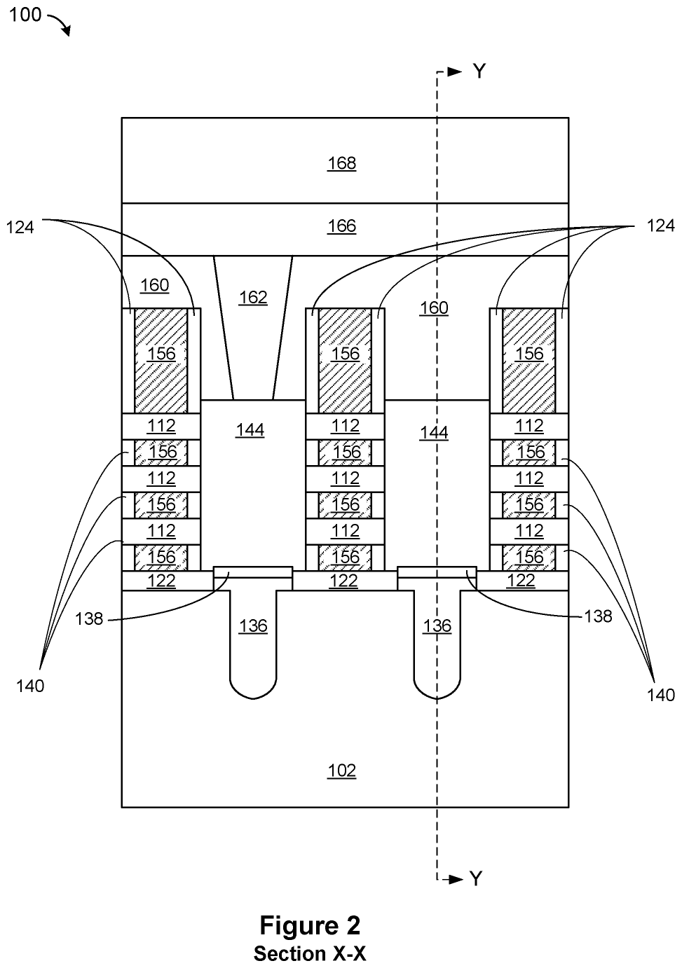

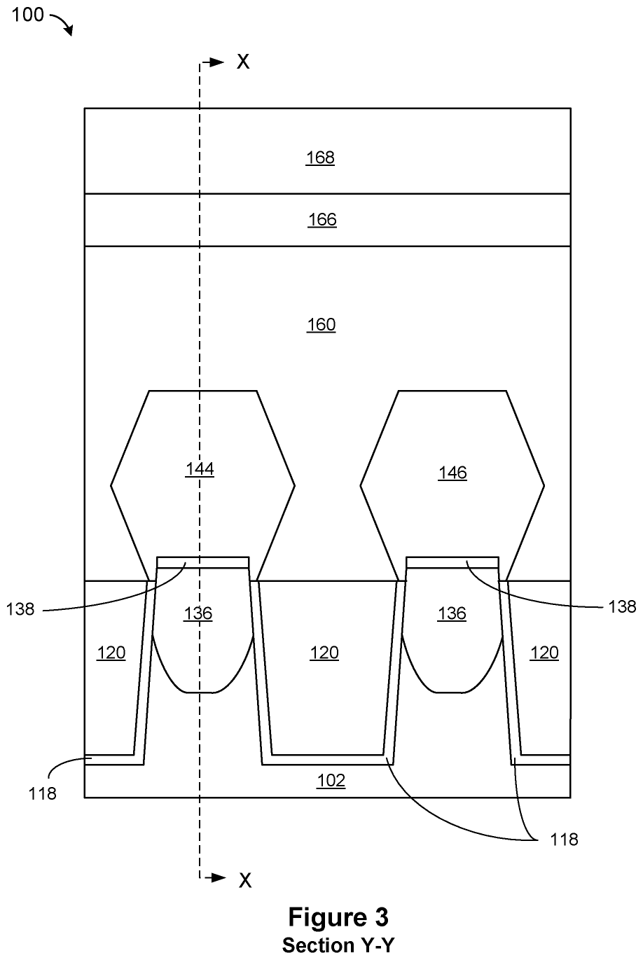

Referring now to FIGS. 1, 2 and 3, a semiconductor structure 100 (hereinafter “structure”) is shown during an intermediate step of a method of fabricating a via, according to an embodiment of the invention. FIG. 1 is a top view of the structure 100. FIGS. 2 and 3 are each a cross-sectional view of the structure 100 along section lines X-X and Y-Y, respectively. The cross-section shown in FIG. 2 is taken in a direction that is perpendicular to the direction taken for FIG. 3. The structure 100 may be formed or provided.

Several steps have been completed to form the structure 100. The structure 100 includes a substrate 102, nanosheet layers, a bottom dielectric isolation (hereinafter “BDI”) 122, inner spacers 140, gate side spacers 124, a liner 118, an shallow trench isolation region (hereinafter “STI”) 120, a sacrificial placeholder 136, a sacrificial placeholder cap 138, an N-FET source drain 144, a P-FET source drain 146, a replacement gate 156 and an interlayer dielectric (hereinafter “ILD”) 160, a contact 162, back end of line (hereinafter “BEOL”) layers 166 (hereinafter “BEOL”) and a carrier wafer 168.

The substrate 102 may be a bulk substrate, which may be made from any of several known semiconductor materials such as, for example, silicon, germanium, silicon-germanium alloy, and compound (e.g. III-V and II-VI) semiconductor materials. Non-limiting examples of compound semiconductor materials include gallium arsenide, indium arsenide, and indium phosphide, or indium gallium arsenide. Typically, the substrate 102 may be approximately, but is not limited to, several hundred microns thick. In other embodiments, the substrate 102 may be a layered semiconductor such as a silicon-on-insulator or SiGe-on-insulator, where a buried insulator layer, separates a base substrate from a top semiconductor layer.

The nanosheet layers may include a bottom sacrificial layer (not shown), and alternating layers of sacrificial semiconductor material and semiconductor channel material, which may include a sacrificial semiconductor material layer (hereinafter “sacrificial layer”), not shown, covered by a semiconductor channel material layer 112 (hereinafter “channel layer”), covered by a sacrificial layer (not shown), covered by a channel layer 112, covered by a sacrificial layer (not shown), covered by a channel layer 112.

The bottom sacrificial layer (not shown) can be formed by epitaxial growth of a sacrificial material on the substrate 102. The alternating layers of sacrificial layer (not shown) and channel layer 112 can be formed by sequential epitaxial growth of alternating layers of a first semiconductor material, and a second semiconductor material stacked one on top of another on the bottom sacrificial layer (not shown). It should be noted that, while a limited number of alternating layers are depicted, any number of alternating layers may be formed. The epitaxial growth of the first and second semiconductor materials that provide the sacrificial semiconductor material layers and the semiconductor channel material layers, respectively, can be performed utilizing any well-known precursor gas or gas mixture. Carrier gases like hydrogen, nitrogen, helium and argon can be used.

The terms “epitaxially growing and/or depositing” and “epitaxially grown and/or deposited” mean the growth of a semiconductor material on a deposition surface of a semiconductor material, in which the semiconductor material being grown has the same crystalline characteristics as the semiconductor material of the deposition surface. In an epitaxial deposition technique, the chemical reactants provided by the source gases are controlled and the system parameters are set so that the depositing atoms arrive at the deposition surface of the semiconductor substrate with sufficient energy to move around on the surface and orient themselves to the crystal arrangement of the atoms of the deposition surface. Therefore, an epitaxial semiconductor material has the same crystalline characteristics as the deposition surface on which it is formed.

Examples of various epitaxial growth techniques include, for example, rapid thermal chemical vapor deposition (RTCVD), low-energy plasma deposition (LEPD), ultra-high vacuum chemical vapor deposition (UHVCVD), low pressure chemical vapor deposition (LPCVD), atmospheric pressure chemical vapor deposition (APCVD) and molecular beam epitaxy (MBE). The temperature for epitaxial deposition typically ranges from approximately 550° C. to approximately 900° C. Although higher temperature typically results in faster deposition, the faster deposition may result in crystal defects and film cracking.

Each sacrificial layer (not shown) is composed of a first semiconductor material which differs in composition from at least the bottom sacrificial layer (not shown) and the channel layer 112. In an embodiment, each sacrificial layer (not shown) may be a silicon-germanium semiconductor alloy and have a germanium concentration less than 50 atomic percent. In another example, each sacrificial layer (not shown) may have a germanium concentration ranging from about 20 atomic percent to about 40 atomic percent. Each sacrificial layer (not shown) can be formed using known deposition techniques or an epitaxial growth technique as described above.

Each channel layer 112 is composed of a second semiconductor material which differs in composition from at least the bottom sacrificial layer (not shown) and the sacrificial layer (not shown). Each channel layer 112 has a different etch rate than the first semiconductor material of sacrificial layer (not shown). The second semiconductor material can be, for example, silicon. The second semiconductor material, for each channel layer 112 can be formed using known deposition techniques or an epitaxial growth technique as described above.

The sacrificial layers (not shown) may have a thickness ranging from about 5 nm to about 15 nm, and the channel layers 112 may have a thickness ranging from about 4 nm to about 12 nm. Each sacrificial layer (not shown) may have a thickness that is the same as, or different from, a thickness of each channel layer 112. In an embodiment, each sacrificial layer (not shown) has an identical thickness. In an embodiment, each channel layer 112 has an identical thickness.

An active device region is defined by removing unwanted portions of the nanosheet layers or nanosheet stack. Remaining portions of the nanosheet stack are formed into fins of nanosheet stack by the removal of the portions of the nanosheet layers, exposing an upper portion of the substrate 102. Section X-X is along the fins of the nanosheet stack, perpendicular to the sacrificial gate 116. Section Y-Y is between adjacent sacrificial gates, parallel to the sacrificial gates and perpendicular to the fins of the nanosheet stack.

The fins of the nanosheet stack may be formed by methods known in the arts, and include steps such as forming a hard mask, on the alternating layers, patterning the hard mask, and subsequent formation of one or more trenches, by removal of portions of each layer of the stacked nanosheet. The trench may form the nanosheet stack into fins of the nanosheet stack by an anisotropic etching technique, such as, for example, reactive ion etching (RIE), and stopping on etching a portion of the substrate 102 between each nanosheet stack.

Each fin of nanosheet stack of nanosheet stack may include a bottom sacrificial layer (not shown), covered by a sacrificial layer (not shown), covered by a channel layer 112, covered by a sacrificial layer (not shown), covered by a channel layer 112, covered by a sacrificial layer (not shown), covered by a channel layer 112. By way of illustration, five fins of the nanosheet stack are depicted in the drawings of the present application, although any number of fins of nanosheet stack may be formed.

The material stacks that can be employed in embodiments of the present invention are not limited to the specific embodiment illustrated in FIGS. 2 and 3. In FIGS. 2 and 3, and only by way of an example, the nanosheet stack includes three layers of sacrificial layers (not shown) alternating with three channel layers 112. The nanosheet stack can include any number of sacrificial layers and channel layers 112. The nanosheet stack is used to produce a gate all around device that includes vertically stacked semiconductor channel material nanosheets for a p-FET or an n-FET.

A sacrificial gate (not shown) is formed orthogonal (perpendicular) to the fins of nanosheet stack. The sacrificial gate (not shown) may include a single sacrificial material or a stack of two or more sacrificial materials. The at least one sacrificial material can be formed by forming a blanket layer (or layers) of a material (or various materials) and then patterning the material (or various materials) by lithography and an etch. The sacrificial gate (not shown) can include any material including, for example, polysilicon, amorphous silicon, or multilayered combinations thereof. In an embodiment where amorphous silicon is used as a material for the sacrificial gate (not shown), a thin layer of SiO2 is deposited first to separate the nanosheet stack from the amorphous silicon. The sacrificial gate (not shown) can be formed using any deposition technique including, for example, chemical vapor deposition (CVD), physical vapor deposition (PVD), high density plasma (HDP) deposition, and spin on techniques.

In an embodiment, the sacrificial gate (not shown) is deposited with a thickness sufficient to fill, or substantially fill, the spaces between adjacent nanosheet structures and cover a horizontal upper surface of the uppermost channel layer 112 of the nanosheet stack. The sacrificial gate (not shown) may be adjacent to vertical side surfaces of the nanosheet stack or fins of nanosheet stack. The sacrificial gate (not shown) may cover an upper horizontal surface of the substrate 102 between adjacent nanosheet stacks. A height of the sacrificial gate (not shown) may be much thicker than the underlying structure and may have a height between 100 nm and 150 nm about the nanosheet stack. Gate patterning may be performed by conventional lithography and etch process, such that portions of the sacrificial gate (not shown) are removed from a subsequently formed source drain region.

Portions of the nanosheet fins are removed selective to the sacrificial gate (not shown), forming a recess (not shown). Remaining portions of the nanosheet fins may be referred to as a stacked nanosheet or a nanosheet stack. The nanosheet stack is used to produce a gate all around device that includes vertically stacked semiconductor channel material nanosheets for a p-FET or an n-FET.

The gate side spacers 124 may be formed vertically aligned with the sacrificial gate (not shown). The gate side spacers 124 may have a vertical side surface aligned with vertical side surfaces of the channel layers 112. The gate side spacers 124 may have a vertical side surface adjacent to a vertical side surface of the sacrificial gate (not shown).

The gate side spacers 124 may be formed after several processes, including for example, conformally depositing or growing a dielectric and performing an anisotropic etch back process. The gate side spacers 124 may include any dielectric material such as silicon nitride (SiN), silicon boron carbon nitride (SiBCN), silicon oxide carbon nitride (SiOCN), SiOC, SiC or aluminum oxide (AlOx), and may include a single layer or may include multiple layers of dielectric material. The gate side spacers 124 may have a thickness ranging from about 3 nm to about 15 nm.

Trenches (not shown) may be formed in the substrate 102 where the portions of the nanosheet fins were removed selective to the sacrificial gate (not shown). The liner 118 may be formed along a lower surface and vertical side surfaces of the substrate 102 in the trench (not shown). The STI 120 may fill remaining portions of the trench on the liner 118.

The liner 118 may be formed by conformally depositing or growing a dielectric material, followed by etch steps. The liner 118 may be deposited using typical deposition techniques, for example, atomic layer deposition (ALD), molecular layer deposition (MLD), chemical vapor deposition (CVD), physical vapor deposition (PVD), high density plasma (HDP) deposition, and spin on techniques, followed by a planarization process, such as CMP, or any suitable etch process. In an embodiment, the liner 118 may include one or more layers. In an embodiment, the liner 118 may include any dielectric material such as silicon nitride, silicon oxide, silicon oxynitride, SiBCN, SiOC, low-k dielectric or any combination of these materials. The liner 118 may have a thickness of approximately 2 nm to 10 nm.

The STI 120 may be formed between adjacent nanosheet fins, between adjacent source drain regions. The STI 120 may be deposited using typical deposition techniques, for example, atomic layer deposition (ALD), molecular layer deposition (MLD), chemical vapor deposition (CVD), physical vapor deposition (PVD), high density plasma (HDP) deposition, and spin on techniques, followed by a planarization process, such as CMP, or any suitable etch process. In an embodiment, the STI 120 may include one or more layers. In an embodiment, the STI 120 may include any dielectric material such as silicon dioxide (SiO2), silicon nitride, silicon oxide, silicon oxynitride, SiBCN, SiOC, low-k dielectric or any combination of these materials.

Outer portions of the sacrificial layers (not shown) may be selectively removed using known techniques. For example, a wet or dry etch process can be used with the appropriate chemistry to remove portions of each of the sacrificial layers (not shown). The material used for the etching process may be selective such that the channel layers 112, the sacrificial gate (not shown), the bottom sacrificial layer (not shown) and the substrate 102 remain and are not etched. After etching, portions of the sacrificial layers (not shown) covered on opposite sides by the sacrificial gate (not shown) may remain as part of the nanosheet stack.

The inner spacer 140 may be formed by conformally depositing or growing a dielectric material, followed by a combination of dry and wet isotropic etch and recessing steps. The inner spacer 140 may be deposited using typical deposition techniques, for example, atomic layer deposition (ALD), molecular layer deposition (MLD), chemical vapor deposition (CVD), physical vapor deposition (PVD), high density plasma (HDP) deposition, and spin on techniques, followed by an isotropic etch process such as a wet etch process, or any suitable etch process. In an embodiment, the inner spacer 140 may include one or more layers. In an embodiment, the inner spacer 140 may include any dielectric material such as silicon oxynitride, silicon nitride, SiBCN, SiOC, or any combination of these materials. The inner spacer 140 may completely fill in spaces between the channel layers 112, where the portions of the sacrificial layers (not shown) had been previously removed. A vertical side surface of the inner spacer 140 may be aligned with a vertical side surface of the channel layers 112 and a vertical side surface of the gate side spacers 142 surrounding the sacrificial gate (not shown).

The bottom sacrificial layer (not shown) may be selectively removed using known techniques. For example, a wet or dry etch process can be used with the appropriate chemistry to remove portions of the bottom sacrificial layer (not shown). The material used for the etching process may be selective such that the channel layers 112, the sacrificial gate (not shown), the gate side spacers 142, the inner spacers 140 and the substrate 102 remain and are not etched. After etching, portions of the sacrificial layers (not shown) covered on opposite sides by the sacrificial gate (not shown) may remain as part of the nanosheet stack.

The BDI 122 may be formed by conformally depositing or growing a dielectric material, followed by a combination of dry and wet isotropic etch and recessing steps. The BDI 122 may be deposited using typical deposition techniques, for example, atomic layer deposition (ALD), molecular layer deposition (MLD), chemical vapor deposition (CVD), physical vapor deposition (PVD), high density plasma (HDP) deposition, and spin on techniques, followed by an isotropic etch process such as a wet etch process, or any suitable etch process. In an embodiment, the BDI 122 may include one or more layers. In an embodiment, the BDI 122 may include any dielectric material such as silicon oxynitride, silicon nitride, SiBCN, SiOC, or any combination of these materials. The BDI 122 may completely fill in spaces between a bottom most channel layer 112 and the substrate 102, where the bottom sacrificial layer (not shown) had been previously removed. A vertical side surface of the BDI 122 may be aligned with a vertical side surface of the channel layers 112 and a vertical side surface of the gate side spacers 124 surrounding the sacrificial gate (not shown).

In an embodiment, the gate side spacers 124, the inner spacer 140 and the BDI 122 may be formed simultaneously. The gate side spacers 124, the inner spacer 140 and the BDI 122 may have vertically aligned side surfaces.

A second trench (not shown) is vertically aligned with the adjacent nanosheet stacks and is formed by removal of a portion of the substrate 102. The sacrificial placeholder 136 is formed in the second trench (not shown). A lower horizontal surface and a portion of vertical side surfaces of the sacrificial placeholder 136 is directly adjacent to the substrate 102. A remaining portion of the vertical side surfaces of the sacrificial placeholder 136 is directly adjacent to the BDI 122. The sacrificial placeholder 136 may be epitaxially grown. The sacrificial placeholder 136, may, for example, be silicon germanium with a germanium concentration approximately ranging from about 25 atomic percent to 85 atomic percent, although percentages greater than 85 percent and less than 25 percent may be used, which may be referred to as silicon germanium (SiGe) with a high or low germanium concentration. The sacrificial placeholder 106 may have a height, ranging from 3 nm-10 nm.

The sacrificial placeholder cap 138 is formed on an upper horizontal surface of the sacrificial placeholder 136. The sacrificial placeholder cap 138 may be formed by epitaxy growth and include materials such as Si or low percentage SiGe.

The N-FET source drain 144 and the P-FET source drain 146 may each separately be epitaxially grown surrounding a vertical portion of the nanosheet stack on opposite sides of the sacrificial gate (not shown). A lower surface of each of the N-FET source drain 144 and the P-FET source drain 146 may be adjacent to an upper surface of the sacrificial placeholder cap 138. A vertical side surface of the each of the N-FET source drain 144 and the P-FET source drain 146 may be adjacent to vertical side surfaces of the inner spacer 140 and vertical side surfaces of the channel layers 112. An upper surface of each of the N-FET source drain 144 and the P-FET source drain 146 may be a greater distance from the substrate 102 than an upper surface of an uppermost channel layer 112.

The sacrificial gate (not shown) and the sacrificial layers (not shown) are removed. The replacement gate 156 is formed where the sacrificial gate (not shown) and the sacrificial layers (not shown) were removed. The sacrificial gate (not shown) may be removed by methods known in the arts. The sacrificial layers (not shown) are removed selective to the channel layers 112, the inner spacers 140, the N-FET source drain 144, the P-FET source drain 146, the gate side spacer 142, the BDI 122, the sacrificial placeholder 136, the sacrificial placeholder cap 138, the STI 120, the liner 118 and the substrate 102. For example, a dry etch process can be used to selectively remove the sacrificial layers (not shown), such as using vapor phased HCl dry etch. An upper surface and a lower surface of the channel layers 112 may be exposed. An upper surface of the BDI 122 may be exposed.

The replacement gate 156 may be conformally formed on the structure 100, according to an exemplary embodiment. The replacement gate 156 is formed in each cavity of the nanosheet stack and surrounding suspended portions of the channel layers 112. The replacement gate 156 forms a layer surrounding exposed portions of the nanosheet stacks. The replacement gate 156 may cover an exposed upper horizontal surface of the substrate 102 and the sacrificial placeholder cap 138, exposed vertical side surfaces of one side of each of the gate side spacers 124 and exposed vertical surfaces of one side of the inner spacers 140. The replacement gate 156 may cover vertical side surfaces, an upper horizontal surface and a lower horizontal surface of the channel layers 110. The replacement gate 156 may fill a space between the gate side spacers 124, where the sacrificial gate (not shown) was removed.

The replacement gate 156 may be deposited using typical deposition techniques, for example, atomic layer deposition (ALD), molecular layer deposition (MLD), and chemical vapor deposition (CVD). In an embodiment, the replacement gate 156 may include more than one layer, for example, a conformal layer of a high-k dielectric material such as HfO₂, ZrO₂, La₂O₃, Al₂O₃, TiO₂, SrTiO₃, LaALO₄, Y₂O₃, HfOₓN_{y}, ZrOₓN_{y}, La₂OₓN_{y}, Al₂OₓN_{y}, TiOₓN_{y}, SrTiOₓN_{y}, LaAlOₓN_{y}, Y₂OₓN_{y}, SiON, SiNₓ, a silicate thereof, and an alloy thereof. In an embodiment, a work function metal of a p-FET device may include a metal nitride, for example, titanium nitride or tantalum nitride, titanium carbide titanium aluminum carbide, or other suitable materials known in the art. In an embodiment, the work function metal of an n-FET device may include, for example, titanium aluminum carbide or other suitable materials known in the art. In an embodiment, the work function metal may include one or more layers to achieve desired device characteristics.

The ILD 160 may be formed by conformally depositing or growing a dielectric material, followed by a CMP or etch steps. The ILD 160 may be deposited using typical deposition techniques, for example, atomic layer deposition (ALD), molecular layer deposition (MLD), chemical vapor deposition (CVD), physical vapor deposition (PVD), high density plasma (HDP) deposition, and spin on techniques, followed by a planarization process, such as CMP, or any suitable etch process. In an embodiment, the ILD 160 may include one or more layers. In an embodiment, the ILD 160 may include any dielectric material such as silicon oxide, silicon oxynitride, silicon nitride, SiBCN, SiOC, low-k dielectric or any combination of these materials. The ILD 160 covers an upper horizontal surface and vertical side surfaces of the the N-FET source drain 144, the P-FET source drain 146, the replacement gate 156 and the gate side spacers 124.

A chemical mechanical polishing (CMP) technique may be used to remove excess material and polish upper surfaces of the structure 100, removing excess material of the ILD 160.

The contact 162 may be formed in an opening in the ILD 160 which exposes an upper horizontal surface of the N-FET source drain 144. The contact 162 may have more than one layer. The contact 162 may be formed from a conductive material layer blanket deposited on top of the structure 100 and may include materials such as, for example copper (Cu), ruthenium (Ru), cobalt (Co), tungsten (W). The conductive material layer can be formed by for example, CVD, PVD, and ALD or a combination thereof. The contact 162 may include a silicide liner such as Ti, Ni, NiPt, an adhesion liner, such as TiN. A chemical mechanical polishing (CMP) technique may be used to remove excess material and polish upper surfaces of the structure 100, exposing an upper horizontal surface of the ILD 160 and an upper horizontal surface of the contact 162. The contact 162 forms a contact to the N-FET source drain 144.

The BEOL layers 166 may be formed on the ILD 160 and on the contact 162. The BEOL layers 166 may also be referred to as frontside interconnect layers. The BEOL layers 166 includes layers of wiring and vias formed above the existing structure, above the contact 162 and the ILD 160. In an embodiment, the BEOL layers 166 may include 12 or more layers of metal lines and visas.

The carrier wafer 168 may be attached to an upper surface of the structure 100, mounted on an upper surface of the BEOL layers 166. The carrier wafer 168 may be attached using conventional wafer bonding process, such as dielectric-to-dielectric bonding or copper-to-copper bonding process.

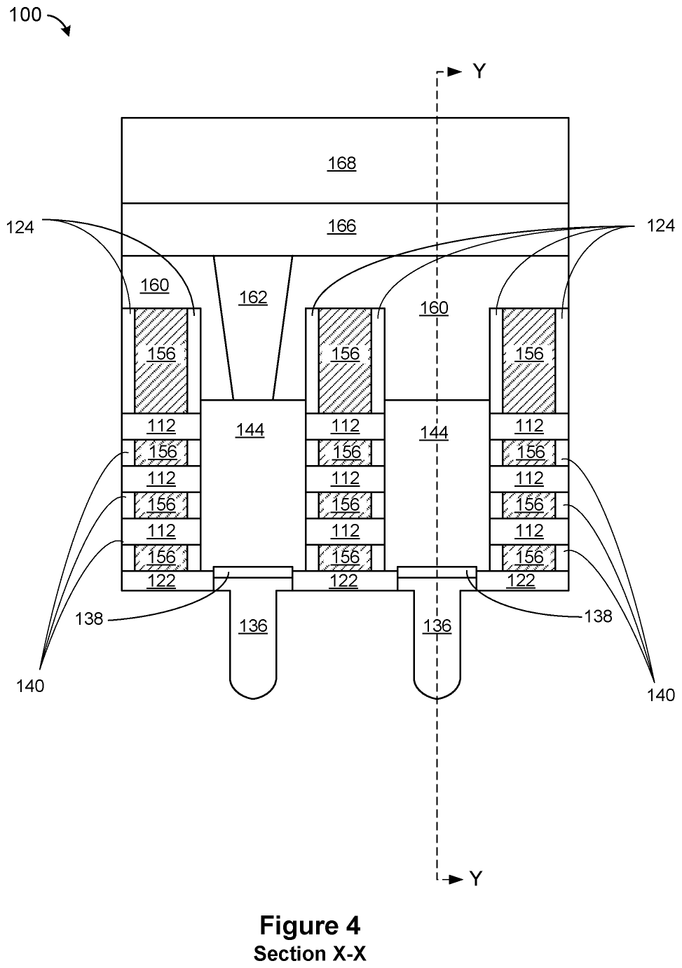

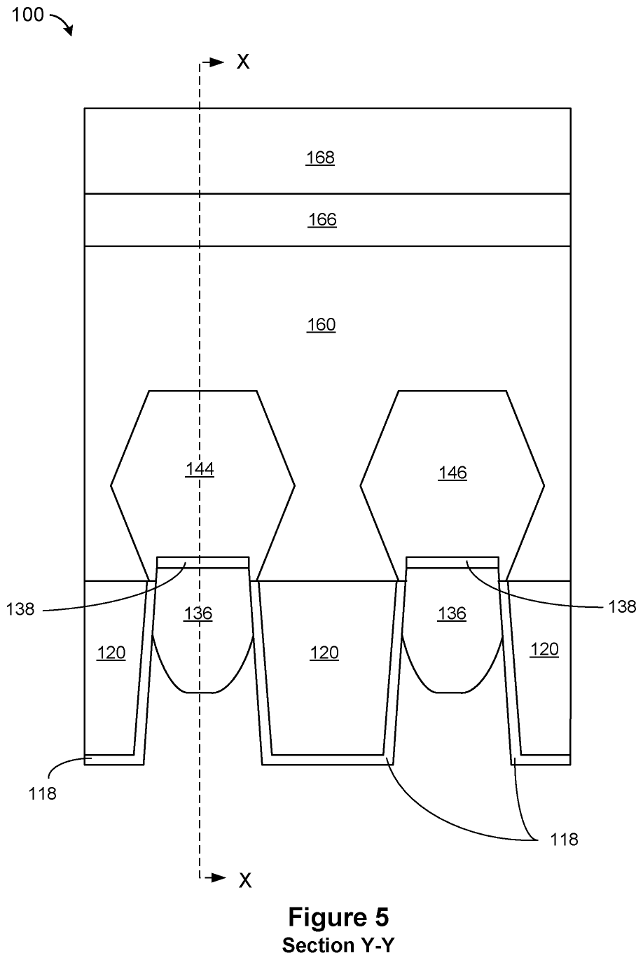

Referring now to FIGS. 4 and 5, the structure 100 is shown according to an exemplary embodiment. FIGS. 4 and 5 are each a cross-sectional view of the structure 100 along section lines X-X and Y-Y, respectively. The structure 100 may be flipped. The substrate 102 is removed.

The structure 100 may be turned such that the carrier wafer 168 is now at a bottom of the structure 100, and a lowermost surface of the substrate 102 is exposed above. Processing will be done at a lower portion of the structure 100, which is physically now flipped. The illustrations will continue without showing the structure 100 flipped, and will show processing of the bottom of the structure 100.

The substrate 102 is removed using a combination of processes steps, such as wafer grinding, CMP, RIE and wet etch process. Removal of the substrate 102 exposes vertical side surfaces and a lower horizontal surface of the sacrificial placeholder 136, a lower horizontal surface of the BDI 22, and vertical side surfaces and a lower horizontal surface of the liner 118.

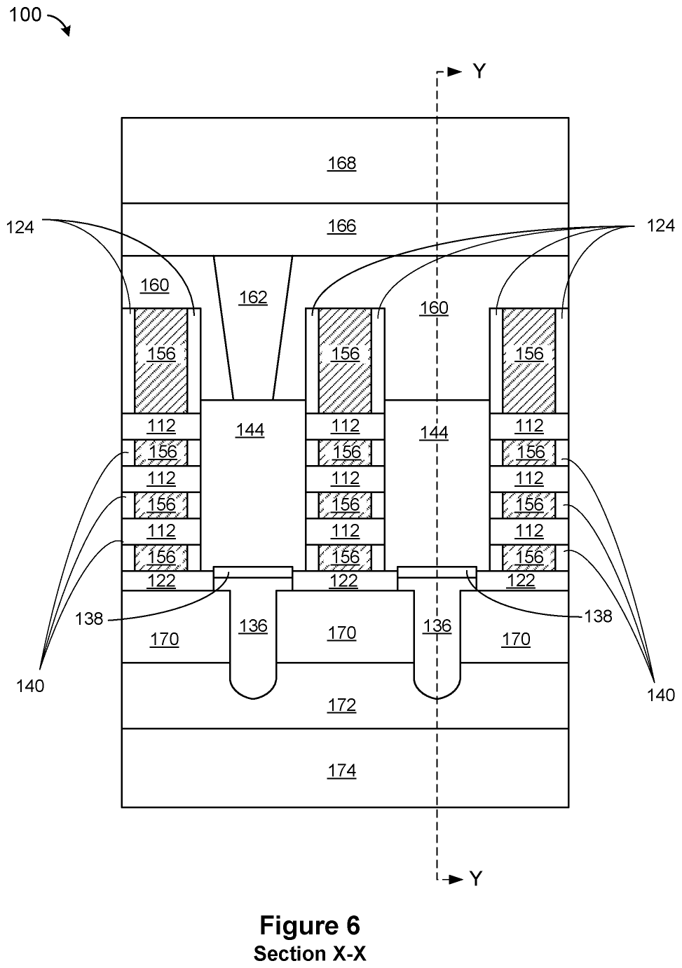

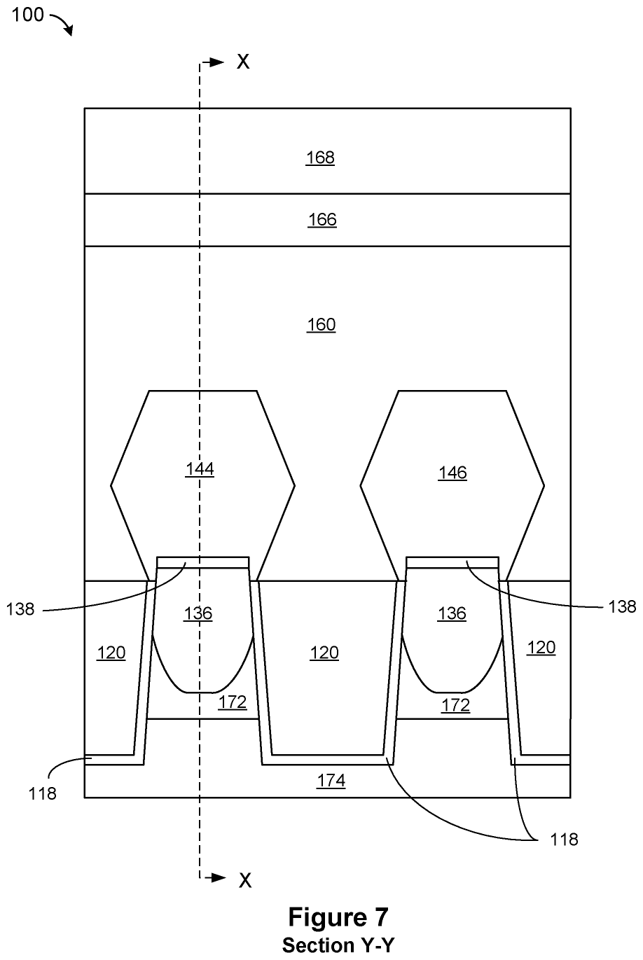

Referring now to FIGS. 6 and 7, the structure 100 is shown according to an exemplary embodiment. FIGS. 6 and 7 are each a cross-sectional view of the structure 100 along section lines X-X and Y-Y, respectively. A first insulator layer 170 is formed. A second insulator 172 is formed. A third insulator 174 is formed.

The first insulator is formed on a lower horizontal surface of the BDI 122. The first insulator 170 may cover a first lower horizontal surface and a portion of a vertical side surface of the sacrificial placeholder 136. A portion of the sacrificial placeholder 136 is exposed. The first insulator 170 may be formed by conformally depositing or growing a dielectric material, followed by CMP and wet or dry etch steps. The first insulator 170 may be deposited using typical deposition techniques, for example, atomic layer deposition (ALD), molecular layer deposition (MLD), chemical vapor deposition (CVD), physical vapor deposition (PVD), high density plasma (HDP) deposition, and spin on techniques, followed by a planarization process, such as CMP, or any suitable etch process. In an embodiment, the first insulator 170 may include one or more layers. In an embodiment, the first insulator 170 may include any dielectric material such as SiO2, aluminum oxide (AlOx), SiC, SiOC and may include a single layer or may include multiple layers of dielectric material.

The second insulator 172 is formed on the first insulator 170 and covers remaining portions of the sacrificial placeholder 136. The second insulator 172 partially fills an opening between adjacent liners 118 surrounding the STI 120. A lower horizontal surface of the second insulator 172 is above a lower horizontal surface of the liner 118. The second insulator 172 may be formed in a manner as described for the first insulator 170. In an embodiment, the second insulator 172 may include any dielectric material such as SiN, SiCN, aluminum oxide (AlOx), SiC, SiOC and may include a single layer or may include multiple layers of dielectric material.

The third insulator 174 is formed on the second insulator 172 and covers remaining portions of the sacrificial placeholder 136. The third insulator 174 fills the opening between adjacent liners 118 surrounding the STI 120 and extends below the adjacent liners 118 surrounding the STI 120. The third insulator 174 may be formed in a manner as described for the first insulator 170. In an embodiment, the third insulator 174 may include any dielectric material such as SiO2, aluminum oxide (AlOx), SiC, SiOC and may include a single layer or may include multiple layers of dielectric material.

The first insulator 170, the second insulator 172, the third insulator 174, the liner 118 and the sacrificial placeholder 136 are each a different material which can be selectively etched. In a preferred embodiment, the first insulator 170 includes SiO2, the second insulator 172 includes SiBCN and the third insulator 174 includes SiO2, the liner 118 includes SiN the liner 184 includes SiCN.

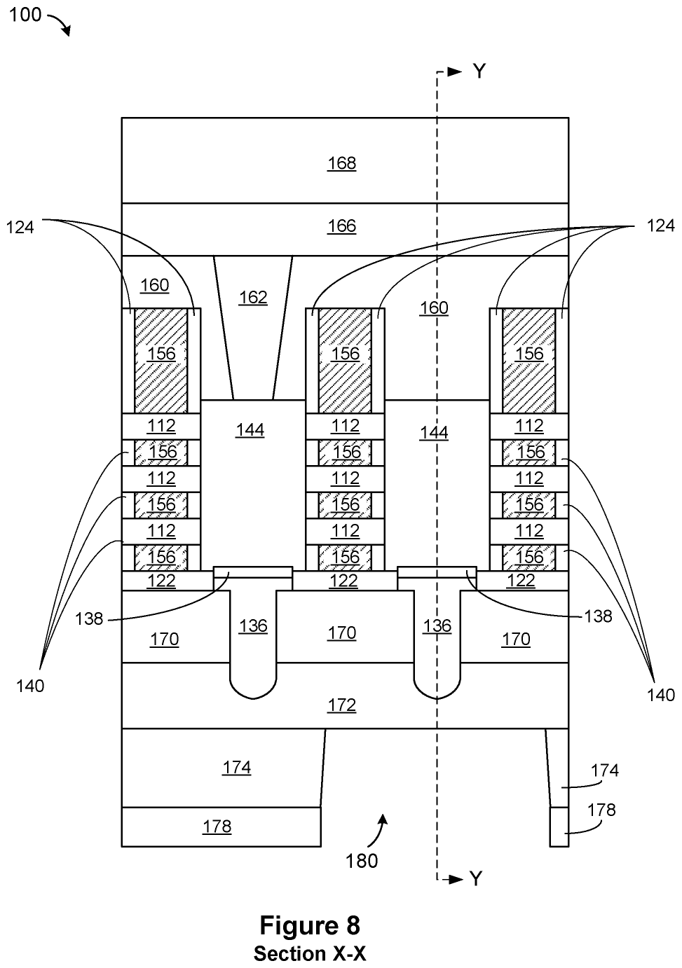

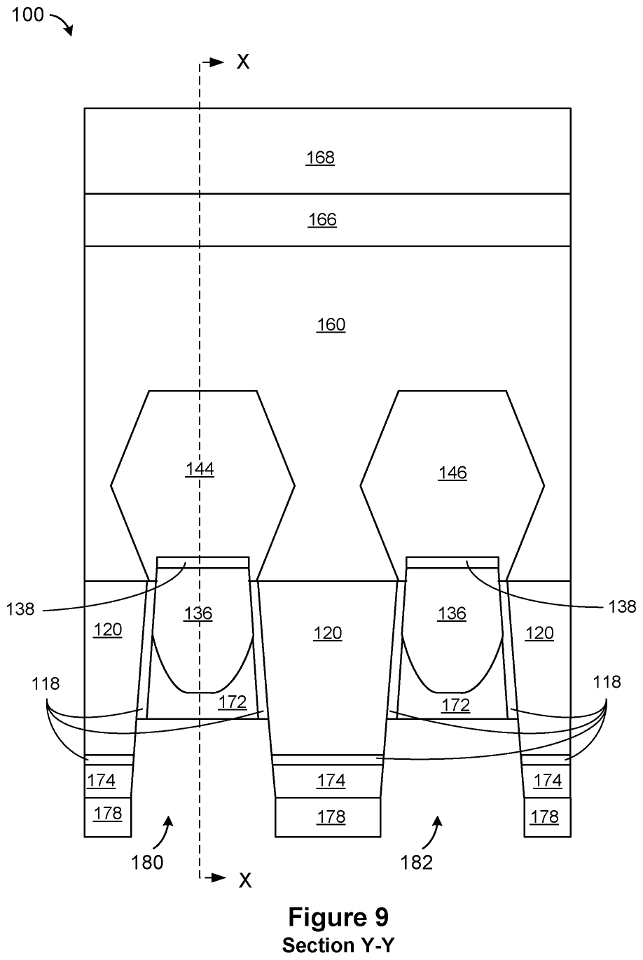

Referring now to FIGS. 8 and 9, the structure 100 is shown according to an exemplary embodiment. FIGS. 8 and 9 are each a cross-sectional view of the structure 100 along section lines X-X and Y-Y, respectively. A hard mask 178 is formed. An opening 180 is formed in the third insulator 174.

The hard mask 178 is formed and patterned on a lower horizontal surface of the structure 100, on the third insulator 174.

Portions of the third insulator 174 are removed by an anisotropic etching technique, such as, for example, reactive ion etching (RIE), removing aligned portions of the third insulator 174, and stopping on etching a portion of the second insulator 172, exposing a lower horizontal surface of the third insulator 174, forming the opening 180 and the opening 182.

The opening 180 in the third insulator 174 is vertically aligned below the N-FET source drain 144 and the opening 182 in the third insulator 174 is vertically aligned below the P-FET source drain 146. The openings 180, 182 may be formed by dry and wet isotropic etch and recessing steps.

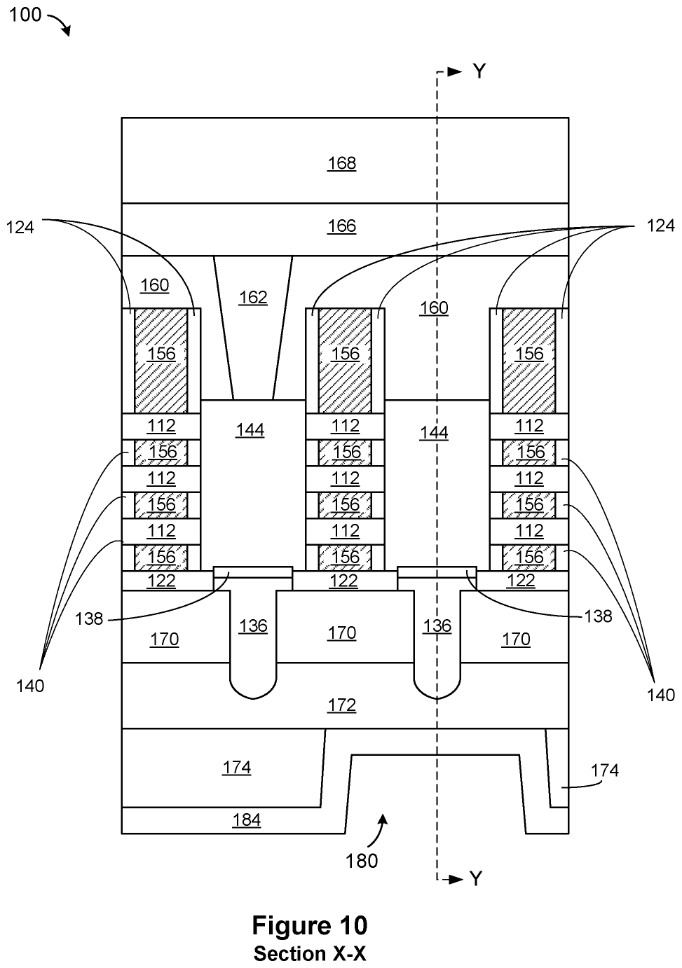

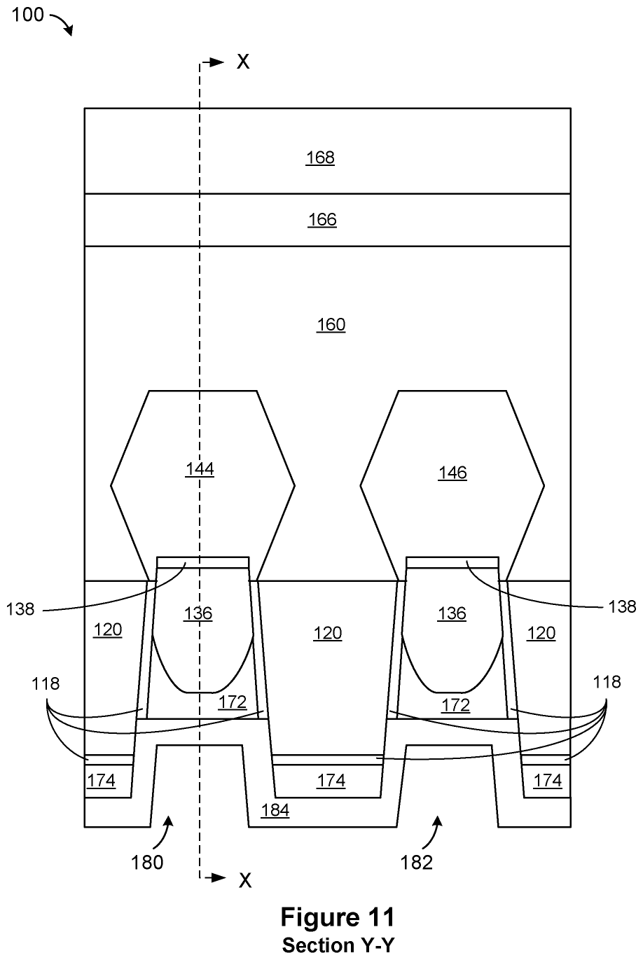

Referring now to FIGS. 10 and 11, the structure 100 is shown according to an exemplary embodiment. FIGS. 10 and 11 are each a cross-sectional view of the structure 100 along section lines X-X and Y-Y, respectively. A liner 184 is formed.

The liner 184 is formed on a lower surface and vertical side surfaces of the third insulator 174, and on a lower horizontal surface of the second insulator 172 in both the opening 180 and the opening 182. The liner 184 may be formed by conformally depositing or growing a dielectric material, followed by etch steps. The liner 184 may be deposited using typical deposition techniques, for example, atomic layer deposition (ALD), molecular layer deposition (MLD), chemical vapor deposition (CVD), physical vapor deposition (PVD), high density plasma (HDP) deposition, and spin on techniques, followed by a planarization process, such as CMP, or any suitable etch process. In an embodiment, the liner 184 may include one or more layers. In an embodiment, the liner 184 may include any dielectric material such as silicon nitride, silicon oxide, silicon oxynitride, SiBCN, SiOC, low-k dielectric or any combination of these materials. The liner 184 may have a thickness of 3˜15 nm.

In an embodiment, the liner 184 includes a different material than the third insulator 174 and the second insulator 172 to allow for selective removal of each material.

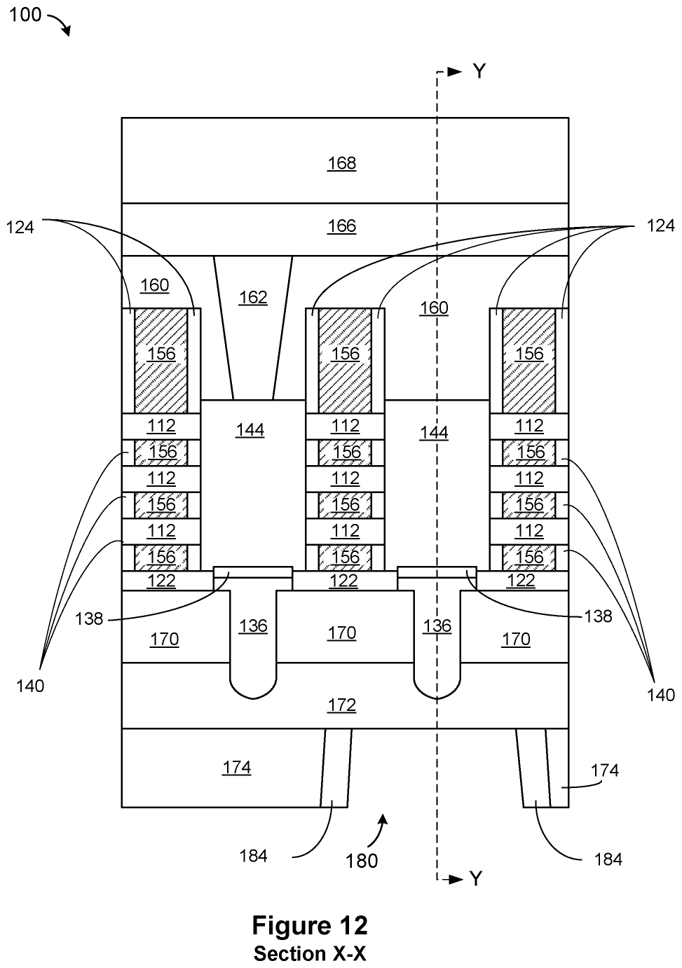

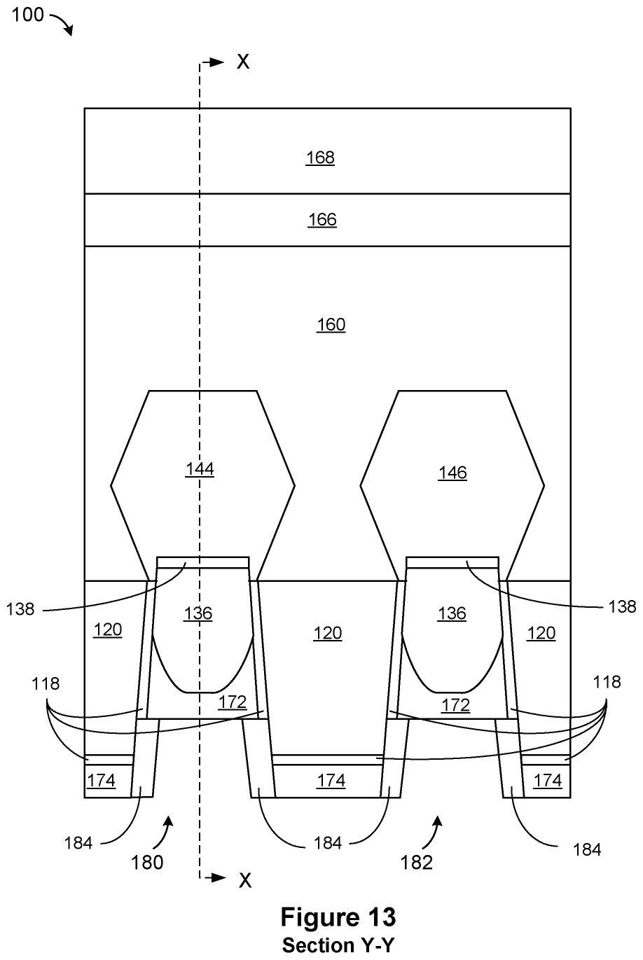

Referring now to FIGS. 12 and 13, the structure 100 is shown according to an exemplary embodiment. FIGS. 12 and 13 are each a cross-sectional view of the structure 100 along section lines X-X and Y-Y, respectively. The hard mask 178 is removed. Portions of the liner 184 are removed.

The portions of the liner 184 are removed by an anisotropic etching technique, such as, for example, reactive ion etching (RIE), removing the liner 184 from lower horizontal surfaces of the third insulator 174 and the second insulator 172, selective to the third insulator 174 and the second insulator 172. The liner 184 remains on vertical side surfaces of the third insulator 174 in both the opening 180 and the opening 182.

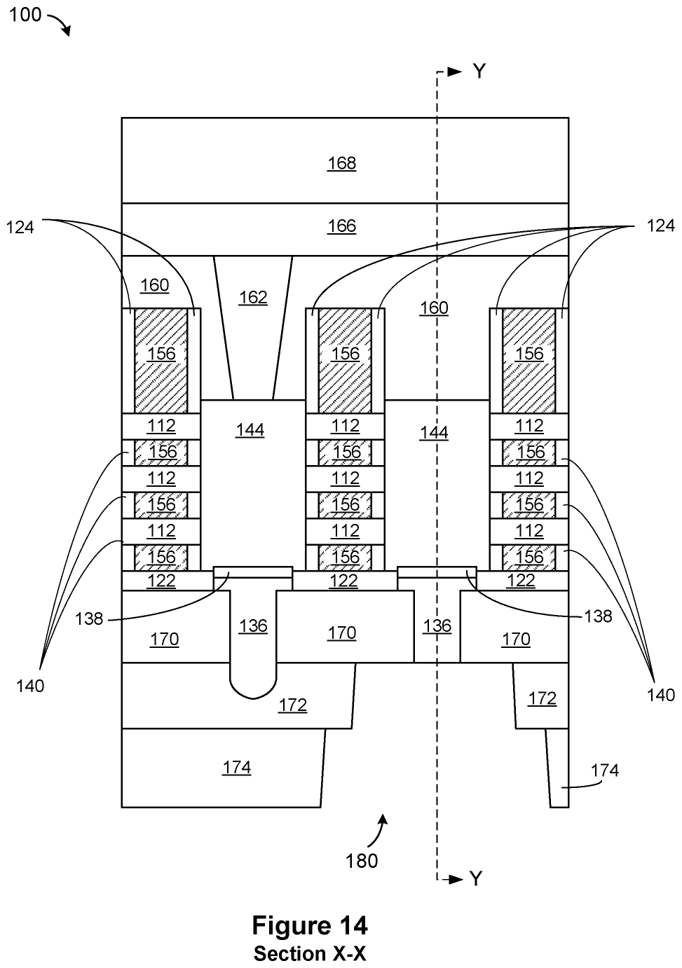

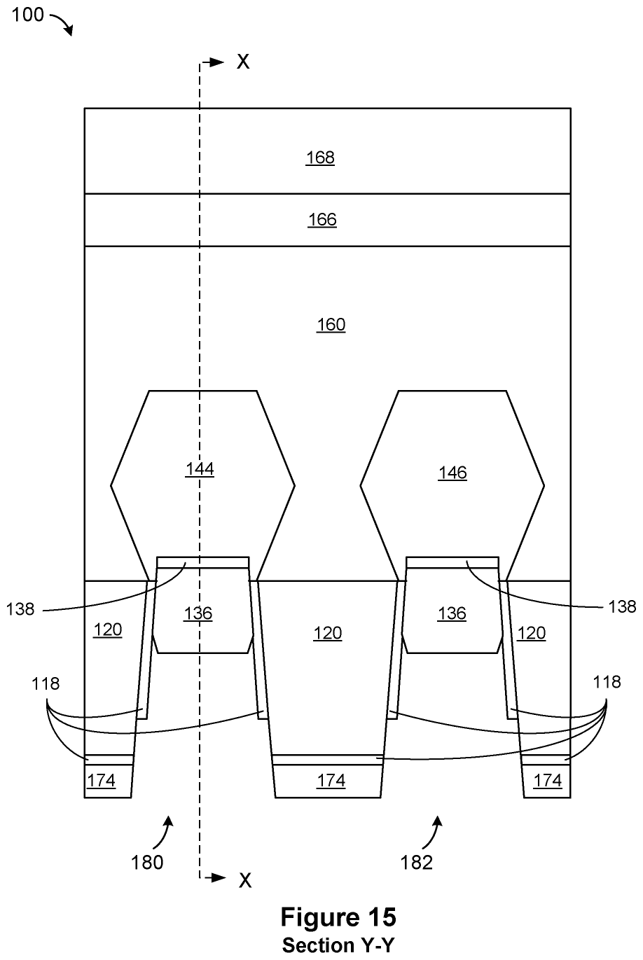

Referring now to FIGS. 14 and 15, the structure 100 is shown according to an exemplary embodiment. FIGS. 14 and 15 are each a cross-sectional view of the structure 100 along section lines X-X and Y-Y, respectively. A portion of the second insulator 172 is removed. A portion of the sacrificial placeholder 136 is removed.

The portion of the second insulator 172 is removed by an anisotropic etching technique, such as, for example, reactive ion etching (RIE), removing the portions of the second insulator 172, selective to the liner 184, the liner 118, the sacrificial placeholder 136 and the first insulator 170. The liner 118 helps protect the STI 120.

The liner 184 protects the third insulator 174, and the liner 118 protects the STI 120 during removal of the portion of the second insulator 172. The liner 184 helps to prevent the openings, 180, 182 from growing wider than necessary, which could cause unintended shorts between contacts to be formed later in the openings 180, 182.

The portion of the sacrificial placeholder 136 is removed by dry etch. A lower horizontal surface of remaining portions of the sacrificial placeholder 136 may be horizontally aligned with a lower horizontal surface of the first insulator 170.

Remaining portions of the liner 184 are removed by either dry etch or wet etch, selective to the third insulator 174, the second insulator 172, the first insulator 170, the sacrificial placeholder 136, the liner 118 and the STI 120.

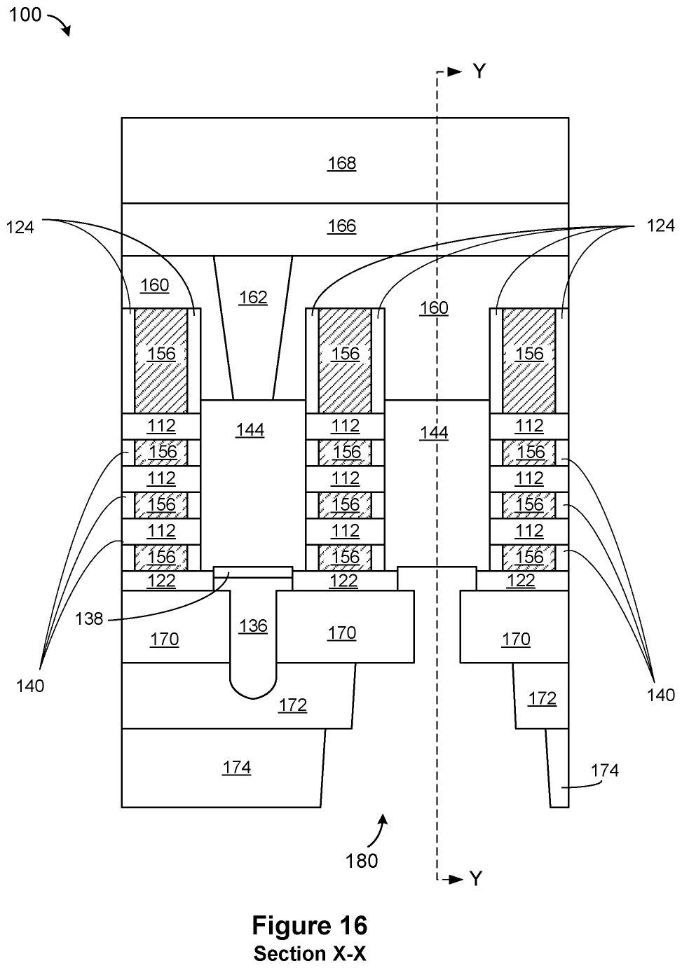

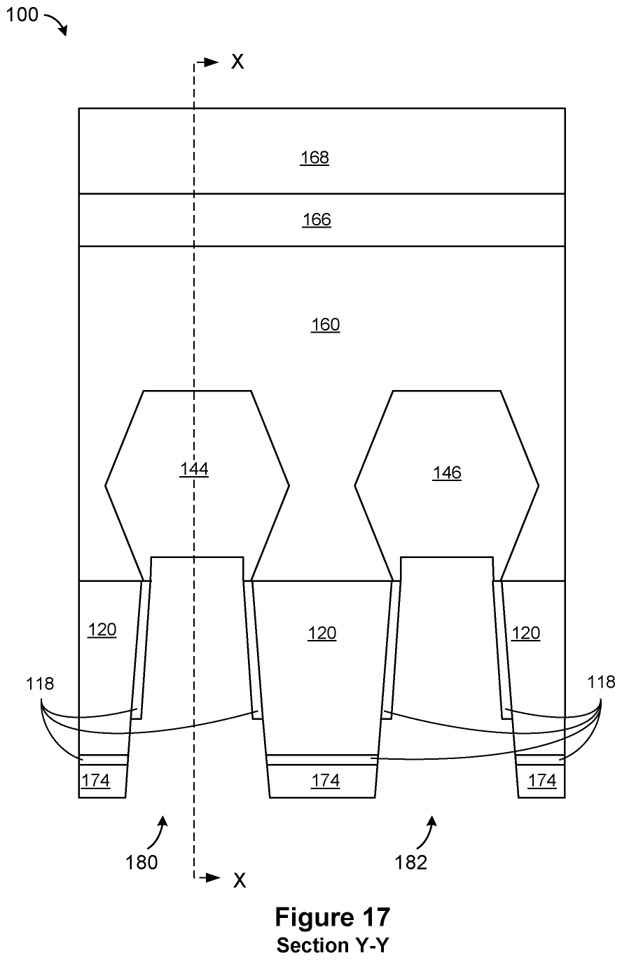

Referring now to FIGS. 16 and 17, the structure 100 is shown according to an exemplary embodiment. FIGS. 16 and 17 are each a cross-sectional view of the structure 100 along section lines X-X and Y-Y, respectively. The sacrificial placeholder 136 and the sacrificial placeholder cap 138 are removed.

The sacrificial placeholder 136 and the sacrificial placeholder cap 138 are removed by an anisotropic etching technique, such as, for example, reactive ion etching (RIE), in one or more steps, increasing a size of the opening 180 below the N-FET source drain 144 and increasing a size of the opening 182 below the P-FET source drain 146. In the opening 180, vertical side surfaces are defined by the third insulator 174, the second insulator 172, the first insulator 170, the liner 118, the BDI 122 and a portion of the N-FET source drain 144. In the opening 180, a upper horizontal surface is defined by the N-FET source drain 144. In the opening 182, vertical side surfaces are defined by the third insulator 174, the second insulator 172, the first insulator 170, the liner 118, the BDI 122 and a portion of the P-FET source drain 146. In the opening 182, a upper horizontal surface is defined by the P-FET source drain 146.

The sacrificial placeholder 136 is removed by dry etch.

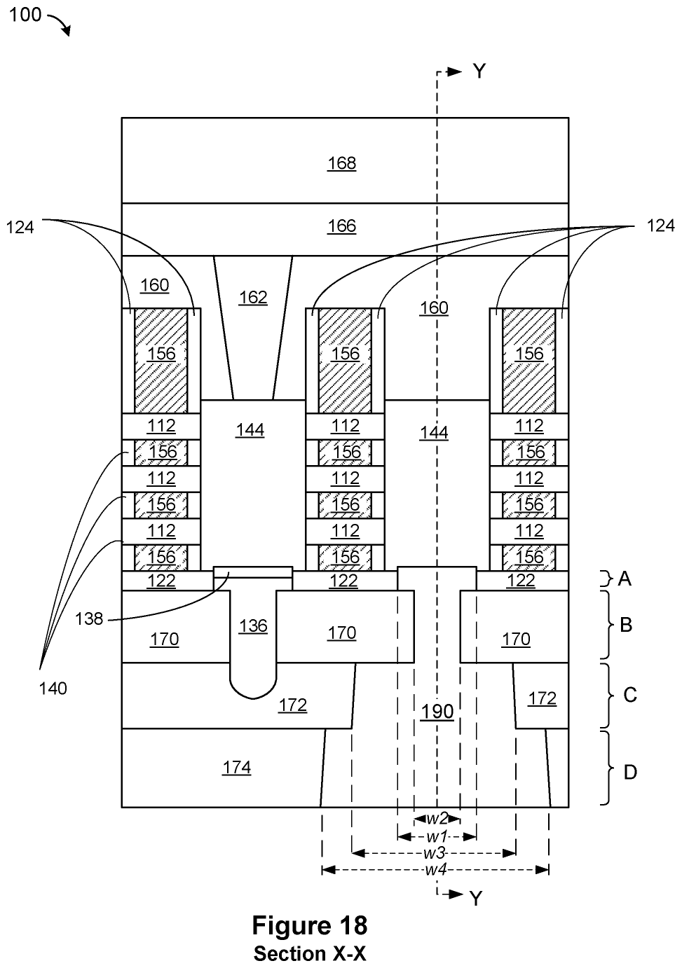

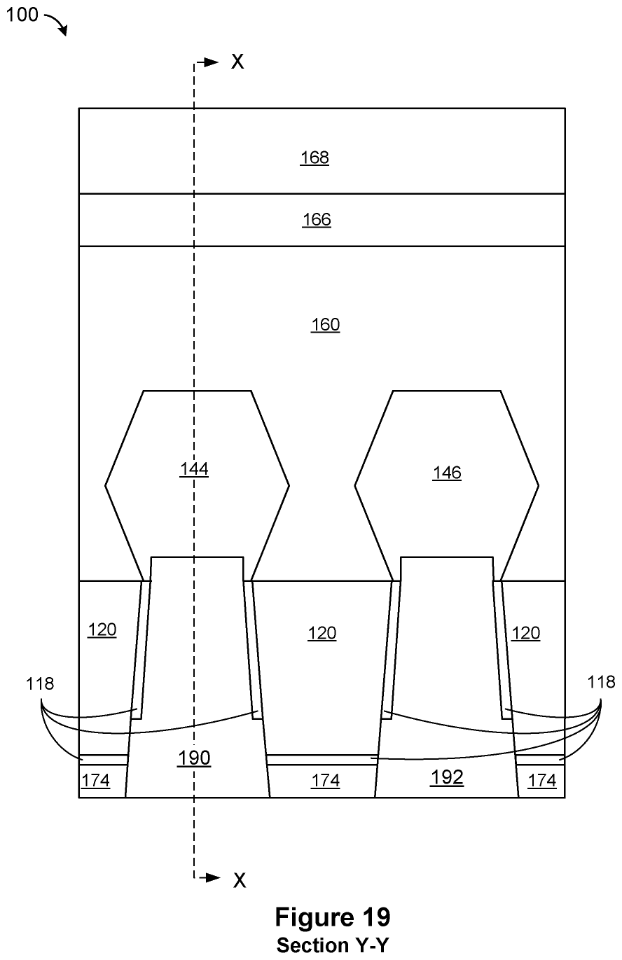

Referring now to FIGS. 18 and 19, the structure 100 is shown according to an exemplary embodiment. FIGS. 18 and 19 are each a cross-sectional view of the structure 100 along section lines X-X and Y-Y, respectively. A contact 190 and a contact 192 are formed.

The contact 190 is formed in the opening 180, filling the opening 180. The contact 192 is formed in the opening 182, filling the opening 182. The contacts 190, 192 may have more than one layer. The contacts 190, 192 may be formed from a conductive material layer blanket deposited on bottom of the structure 100 and may include materials such as, for example copper (Cu), ruthenium (Ru), cobalt (Co), tungsten (W). The conductive material layer can be formed by for example, CVD, PVD, and ALD or a combination thereof. The contacts 190, 192 may include a silicide liner such as Ti, Ni, NiPt, an adhesion liner, such as TiN. A chemical mechanical polishing (CMP) technique may be used to remove excess material and polish lower surfaces of the structure 100, exposing a lower horizontal surface of the third insulator 174 and a lower horizontal surface of the contacts 190, 192. The contact 162 forms a contact to the N-FET source drain 144.

An upper horizontal surface of the contact 190 is directly adjacent to a lower horizontal surface of the N-FET source drain 144. Vertical side surfaces of the contact 190 are directly adjacent to vertical side surface of the third insulator 174, the second insulator 172, the first insulator 170, the liner 118, the BDI 122 and a portion of the N-FET source drain 144. A first lower horizontal surface of the contact 190 is directly adjacent to an upper horizontal surface of the first insulator 170. A second lower horizontal surface of the contact 190 is horizontally aligned with a lower horizontal surface of the third insulator 174.

An upper horizontal surface of the contact 192 is directly adjacent to a lower horizontal surface of the P-FET source drain 146. Vertical side surfaces of the contact 192 are directly adjacent to vertical side surface of the third insulator 174, the second insulator 172, the first insulator 170, the liner 118, the BDI 122 and a portion of the P-FET source drain 146. A first lower horizontal surface of the contact 192 is directly adjacent to an upper horizontal surface of the first insulator 170. A second lower horizontal surface of the contact 192 is horizontally aligned with a lower horizontal surface of the third insulator 174.

In this embodiment, the source drain 144 which has the contact 162 to the BEOL 166 does not have a contact formed on a lower part of the structure 100. In alternate embodiments, each of the N-FET source drain 144 and the P-FET source drain 146 may have a contact to the BEOL 166 or a bottom contact such as the contact 190, 192. In a further alternate embodiment, each of the N-FET source drain 144 and the P-FET source drain 146 may have a contact to both the BEOL 166 and have a bottom contact such as the contact 190, 192.

The contact 190 has a first region A, a second region B, a third region C and a fourth region D. The first region A is directly above the second region B, the second region B is directly above the third region C and the third region C is directly below the fourth region D. Hereinafter, the first region A, the second region B, the third region C, and the fourth region D may be referred to, respectfully, as a top portion, a middle portion, a first bottom portion, and a second bottom portion of the contact 190. The region A of the contact 190 has an upper surface which is above a lower surface of the N-FET source drain 144. The region A has vertical side surfaces directly adjacent to a portion of the vertical side surfaces of the N-FET source drain 144. The region A has vertical side surfaces directly adjacent to vertical side surfaces of the BDI 122. The region B of the contact 190 has vertical side surfaces directly adjacent to vertical side surfaces of the first insulator 170. The region C has vertical side surfaces directly adjacent to vertical side surfaces of the second insulator 172. The region D has vertical side surfaces directly adjacent to vertical side surfaces of the third insulator 174.

The region A has a width w1. The region B has a width w2, which is less than the width w1. The region C has a width w3, which is greater than the width w1. The region D has a width w4, which is greater than the width w3.

In this invention, forming the first insulator 170, the second insulator 172 and the third insulator 174 on the bottom of the structure 100, allows selective removal in sequence of portions of the third insulator 174, the second insulator 172 and the first insulator 170. This selective removal reduces a chance of bottom openings to the source drain overlapping and causing shorts between adjacent source drains when the contacts 190, 192 are formed in the bottom openings. The liner 184 additionally protects vertical side surfaces of the third insulator 174 when removing the portion of the second insulator 172.

According to an embodiment of the present invention, a semiconductor structure is provided. The semiconductor structure including a source drain region directly adjacent to a nanosheet stack, and a bottom contact directly below the source drain region, where the bottom contact includes a top portion directly below the source drain region, a middle portion directly below the top portion, a first bottom portion directly below the middle portion and a second bottom portion directly below the first bottom portion, where the middle portion is more narrow than the top portion and more narrow than the first bottom portion.

An embodiment where the top portion includes a first width greater than a second width of the middle portion, where the first bottom portion includes a third width greater than the first width, where the second bottom portion includes a width greater than the third width. An embodiment where a bottom isolation dielectric directly below the nanosheet stack surrounds the top portion. An embodiment further includes a first insulator directly below a bottom isolation dielectric directly below the nanosheet stack, where the first insulator surrounds vertical side surfaces of the middle portion. An embodiment further includes a second insulator directly below the first insulator, where the second insulator surrounds vertical side surfaces of the first bottom portion, where the second insulator includes a different material than the first insulator. An embodiment further includes a third insulator directly below the second insulator, where the third insulator surrounds vertical side surfaces of the second bottom portion, where the third insulator includes a different material than the first insulator and includes a different material than the second insulator. An embodiment where a lower horizontal surface of the source drain region is below an upper horizontal surface of the bottom contact.

According to an embodiment of the present invention, a semiconductor structure is provided. The semiconductor structure including a bottom contact directly below a source drain region, where the bottom contact includes a top portion directly below the source drain region, a middle portion directly below the top portion and a first bottom portion directly below the middle portion, where the middle portion is more narrow than the top portion and more narrow than the first bottom portion.

An embodiment where the top portion includes a first width greater than a second width of the middle portion, where the first bottom portion includes a third width greater than the first width. An embodiment where a bottom isolation dielectric directly below the nanosheet stack surrounds the top portion. An embodiment further includes a first insulator directly below a bottom isolation dielectric directly below the nanosheet stack, where the first insulator surrounds vertical side surfaces of the middle portion. An embodiment further includes a second insulator directly below the first insulator, where the second insulator surrounds vertical side surfaces of the first bottom portion, where the second insulator includes a different material than the first insulator. An embodiment where a lower horizontal surface of the source drain region is below an upper horizontal surface of the bottom contact.

According to an embodiment of the present invention, a semiconductor structure is provided. The semiconductor structure including a source drain region directly adjacent to a nanosheet stack, and a bottom contact directly below the source drain region, where the bottom contact includes a top portion directly below the source drain region and a middle portion directly below the top portion, where the middle portion is more narrow than the top portion and more narrow than the first bottom portion.

An embodiment where the top portion includes a first width greater than a second width of the middle portion. An embodiment where a bottom isolation dielectric directly below the nanosheet stack surrounds the top portion. An embodiment further includes a first insulator directly below a bottom isolation dielectric directly below the nanosheet stack, where the first insulator surrounds vertical side surfaces of the middle portion. An embodiment where a lower horizontal surface of the source drain region is below an upper horizontal surface of the bottom contact.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the invention. The terminology used herein was chosen to best explain the principles of the embodiment, the practical application or technical improvement over technologies found in the marketplace, or to enable others of ordinary skill in the art to understand the embodiments disclosed herein.

What is claimed is:

1. A semiconductor device comprising:
a source drain region directly adjacent to a nanosheet stack; and
a bottom contact directly below the source drain region, wherein the bottom contact comprises a top portion directly below the source drain region, a middle portion directly below the top portion, a first bottom portion directly below the middle portion and a second bottom portion directly below the first bottom region, wherein the middle portion is more narrow than the top portion and more narrow than the first bottom portion.

2. The semiconductor device according to claim 1, wherein top portion comprises a first width greater than a second width of the middle portion, wherein the first bottom portion comprises a third width greater than the first width, wherein the second bottom portion comprises a width greater than the first bottom portion.

3. The semiconductor device according to claim 1, wherein a bottom isolation dielectric directly below the nanosheet stack surrounds the top portion.

4. The semiconductor device according to claim 1, further comprising:
a first insulator directly below a bottom isolation dielectric directly below the nanosheet stack, wherein the first insulator surrounds vertical side surfaces of the middle portion.

5. The semiconductor device according to claim 4, further comprising:
a second insulator directly below the first insulator, wherein the second insulator surrounds vertical side surfaces of the first bottom portion, wherein the second insulator comprises a different material than the first insulator.

6. The semiconductor device according to claim 5, further comprising:
a third insulator directly below the second insulator, wherein the third insulator surrounds vertical side surfaces of the second bottom portion, wherein the third insulator comprises a different material than the first insulator and comprises a different material than the second insulator.

7. The semiconductor device according to claim 1, wherein a lower horizontal surface of the source drain region is below an upper horizontal surface of the bottom contact.

8. A semiconductor device comprising:
a bottom contact directly below a source drain region, wherein the bottom contact comprises a top portion directly below the source drain region, a middle portion directly below the top portion and a first bottom portion directly below the middle portion, wherein the middle portion is more narrow than the top portion and more narrow than the first bottom portion.

9. The semiconductor device according to claim 8, wherein the top portion comprises a first width greater than a second width of the middle portion, wherein the first bottom portion comprises a third width greater than the first width.

10. The semiconductor device according to claim 8, wherein a bottom isolation dielectric directly below the nanosheet stack surrounds the top portion.

11. The semiconductor device according to claim 8, further comprising:
a first insulator directly below a bottom isolation dielectric directly below the nanosheet stack, wherein the first insulator surrounds vertical side surfaces of the middle portion.

12. The semiconductor device according to claim 11, further comprising:
a second insulator directly below the first insulator, wherein the second insulator surrounds vertical side surfaces of the first bottom portion, wherein the second insulator comprises a different material than the first insulator.

13. The semiconductor device according to claim 11, wherein a lower horizontal surface of the source drain region is below an upper horizontal surface of the bottom contact.

13. A semiconductor device comprising:
a source drain region directly adjacent to a nanosheet stack; and
a bottom contact directly below the source drain region, wherein the bottom contact comprises a top portion directly below the source drain region and a middle portion directly below the top portion, wherein the middle portion is more narrow than the top portion.

14. The semiconductor device according to claim 13, wherein the top portion comprises a first width greater than a second width of the middle portion.

15. The semiconductor device according to claim 13, wherein a bottom isolation dielectric directly below the nanosheet stack surrounds the top portion.

16. The semiconductor device according to claim 13, further comprising:
a first insulator directly below a bottom isolation dielectric directly below the nanosheet stack, wherein the first insulator surrounds vertical side surfaces of the middle portion.

17. The semiconductor device according to claim 13, wherein a lower horizontal surface of the source drain region is below an upper horizontal surface of the bottom contact.
